(19) United States
(12) Patent Application Publication
(10) Pub. No.: US 2025/0192513 A1
(43) Pub. Date: Jun. 12, 2025

(54) DRIVE CIRCUIT AND RANGING SENSOR

(71) Applicant: Sharp Semiconductor Innovation Corporation, Tenri City (JP)

(72) Inventors: Takayuki SHIMIZU, Tenri City (JP); Takahiro Inoue, Tenri City (JP); Hideki Sato, Tenri City (JP); Tetsuro Ikeda, Tenri City (JP); Ryuhji Arimura, Tenri City (JP)

(21) Appl. No.: 18/969,538

(22) Filed: Dec. 5, 2024

(30) Foreign Application Priority Data
Dec. 11, 2023 (JP) 2023-208459

(51) Int. Cl. H01S 5/042; G01S 7/484; G01S 7/4865; G01S 17/08

(52) U.S. Cl. CPC H01S 5/0428; G01S 7/484; G01S 7/4865; G01S 17/08

(57) ABSTRACT

A drive circuit includes: a n-channel field effect transistor including a gate, a drain into which an electric current that is part of a drive current that drives a light-emitting element flows, and a source; a capacitor that grounds the gate by means of alternating current; and a source drive circuit that drives the source through a signal that is in accordance with an inputted pulse signal.

### CROSS-REFERENCE TO RELATED APPLICATION

The present application claims priority from Japanese Application JP2023-208459, the content of which is hereby incorporated by reference into this application.

### BACKGROUND OF THE INVENTION

### 1. Field of the Invention

The present disclosure relates to drive circuits and ranging sensors.

### 2. Description of the Related Art

PCT International Application Publication No. WO2017/209206 discloses a time-of-flight (ToF) type of ranging sensor. In this ranging sensor, a vertical-cavity surface-emitting laser (VCSEL) driver drives a VCSEL. The VCSEL can hence emit light pulses. A single photon avalanche diode (SPAD) array receives the light reflected by a detection target. The SPAD array can hence output pulse signals (see paragraphs 0017 to 0020 and 0022).

### SUMMARY

In the ranging sensor disclosed in PCT International Application Publication No. WO2017/209206, ranging precision increases with a decrease in the pulse width of the light pulse emitted by the VCSEL. However, it is difficult in this ranging sensor to have the VCSEL to stably emit light pulses with short a pulse width.

The present disclosure, in an aspect thereof, has been made in view of this issue. The present disclosure, in an aspect thereof, has an object to provide, for example, a drive circuit and a ranging sensor that are capable of stably causing a light-emitting element to emit light pulses with short a pulse width.

The present disclosure, in an aspect thereof, is directed to a drive circuit including: a n-channel field effect transistor including: a gate; a drain into which an electric current that is part of a drive current that drives a light-emitting element flows; and a source; a capacitor that grounds the gate by means of alternating current; and a source drive circuit that drives the source through a signal that is in accordance with an inputted pulse signal.

### BRIEF DESCRIPTION OF THE DRAWINGS

FIG. 1 is a schematic cross-sectional view of a ranging sensor in accordance with Embodiment 1 and a target of the ranging performed by the ranging sensor.

FIG. 2 is a block diagram of a light-receiving integrated circuit (IC) and a light-emitting element in the ranging sensor in accordance with Embodiment 1.

FIG. 3 is a set of diagrams showing examples of a first time difference histogram and a second time difference histogram generated by a histogram generation/distance computation unit in the ranging sensor in accordance with Embodiment 1.

FIG. 4 is a circuit diagram of a drive circuit and a light-emitting element in the ranging sensor in accordance with Embodiment 1.

FIG. 5 is a diagram showing a waveform of a drive signal inputted to a drive circuit in the ranging sensor in accordance with Embodiment 1 and a waveform of a drive current outputted from this drive circuit.

FIG. 6 is a diagram showing a waveform of a drive signal inputted to the input terminals of a first inverter and a second inverter in a drive circuit in the ranging sensor in accordance with Embodiment 1 and a waveform of an inverted pulse signal outputted from the output terminals of the first inverter and the second inverter.

FIG. 7 is a circuit diagram of an equivalent circuit of a light-emitting element, an anode-side gold wire, a cathode-side gold wire, and a snubber circuit in the ranging sensor in accordance with Embodiment 1.

FIG. 8 is a graph representing an exemplary waveform of a drive current outputted by a drive circuit in the ranging sensor in accordance with Embodiment 1 and an exemplary waveform of a drive current outputted by the drive circuit when no snubber circuit is provided in the drive circuit.

FIG. 9 is a circuit diagram of a drive circuit in a ranging sensor in accordance with Embodiment 2.

FIG. 10 is a circuit diagram of a drive circuit in a ranging sensor in accordance with Embodiment 3.

### DETAILED DESCRIPTION OF THE INVENTION

The following will describe embodiments of the present disclosure with reference to drawings. Note that identical and equivalent elements in the drawings are denoted by the same reference numerals, and description thereof is not repeated.

### 1 Embodiment 1

### 1.1 Ranging Sensor

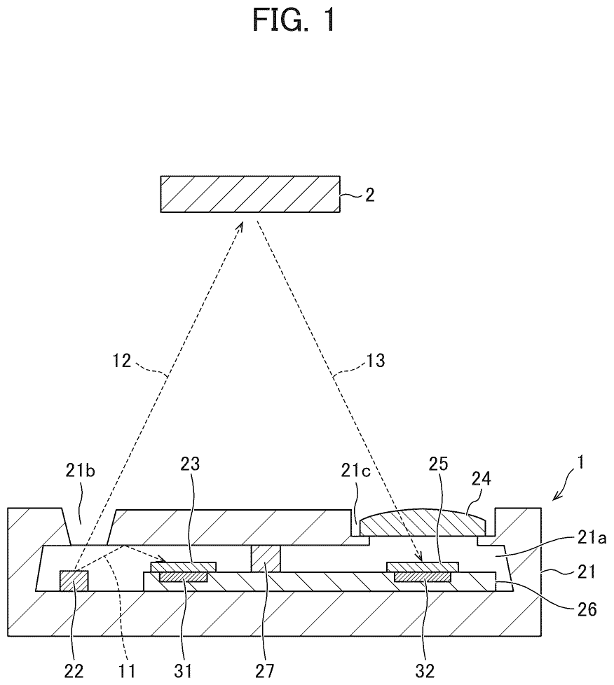

FIG. 1 is a schematic cross-sectional view of a ranging sensor in accordance with Embodiment 1 and a target of the ranging performed by the ranging sensor.

A ranging sensor 1 in accordance with Embodiment 1 shown in FIG. 1 is a time-of-flight (ToF) type of ranging sensor. Therefore, the ranging sensor 1 emits a second pulsed beam 12. The emitted, second pulsed beam 12 is reflected by a target 2 to produce a reflected pulsed beam 13, which is then received by the ranging sensor 1. The ranging sensor 1 can hence perform ranging on the target 2 based on the time taken from the emission of the second pulsed beam 12 to reception of the reflected pulsed beam 13.

Referring to FIG. 1, the ranging sensor 1 includes a package 21, a light-emitting element 22, a first optical filter 23, a converging lens 24, a second optical filter 25, a light-receiving integrated circuit (IC) 26, and a light-shielding wall 27. The light-receiving IC 26 includes a first light-receiving element 31 and a second light-receiving element 32.

The package 21 has an internal space 21a, a first hole 21b, and a second hole 21c formed therein. The internal space 21a accommodates the light-emitting element 22, the first optical filter 23, the second optical filter 25, the light-receiving IC 26, and the light-shielding wall 27. The first hole 21b extends from the internal space 21a to the outside of the package 21. The second hole 21c extends from the internal space 21a to the outside of the package 21. The second hole 21c contains the converging lens 24 therein.

The light-emitting element 22 emits pulsed beams including a first pulsed beam 11 and the second pulsed beam 12. The first pulsed beam 11 travels through the internal space 21a of the package 21 without leaving the package 21, thereby reaching the first light-receiving element 31 via the first optical filter 23. The second pulsed beam 12 travels through the internal space 21a and exits the package 21 via the first hole 21b, thereby reaching the target 2. The reflected pulsed beam 13, generated by the second pulsed beam 12 being reflected by the target 2, travels outside the package 21 and then through the converging lens 24 and the second optical filter 25, thereby reaching the second light-receiving element 32. The light-emitting element 22 is a vertical-cavity surface-emitting laser (VCSEL). The light-emitting element 22 may be a light-emitting element other than a VCSEL.

The first optical filter 23 transmits the first pulsed beam 11. The first optical filter 23 selectively transmits light that has the wavelength of the first pulsed beam 11 and wavelengths close to this wavelength.

The first light-receiving element 31 receives the first pulsed beam 11 that has transmitted through the first optical filter 23 and outputs a first pulse signal in accordance with the received, first pulsed beam 11. The first light-receiving element 31 is a single photon avalanche diode (SPAD) array. The first light-receiving element 31 may be a light-receiving element other than a SPAD array.

The converging lens 24 transmits the reflected pulsed beam 13. The converging lens 24 converges the reflected pulsed beam 13 onto the second light-receiving element 32.

The second optical filter 25 transmits the reflected pulsed beam 13 that has transmitted through the converging lens 24. The second optical filter 25 selectively transmits light that has the wavelength of the second pulsed beam 12 and wavelengths close to this wavelength.

The second light-receiving element 32 receives the reflected pulsed beam 13 that has transmitted through the second optical filter 25 and outputs a second pulse signal in accordance with the reflected pulsed beam 13 thus received. The second light-receiving element 32 is a SPAD array. The second light-receiving element 32 may be a light-receiving element other than a SPAD array.

The light-shielding wall 27 segregates the region where the second light-receiving element 32 is disposed from the region where the light-emitting element 22 and the first light-receiving element 31 are disposed. The light-shielding wall 27 blocks light. Hence, the light-shielding wall 27 hinders the first pulsed beam 11 from reaching the second light-receiving element 32.

The light-receiving IC 26 acquires the distance between the ranging sensor 1 and the target 2 from the outputted, first pulse signal and the outputted, second pulse signal.

The first optical filter 23 and the first light-receiving element 31 may be referred to as the reference-side optical filter and the reference-side light-receiving element respectively. The second optical filter 25 and the second light-receiving element 32 may be referred to as the return-side optical filter and the return-side light-receiving element respectively.

### 1.2 Light-Receiving IC

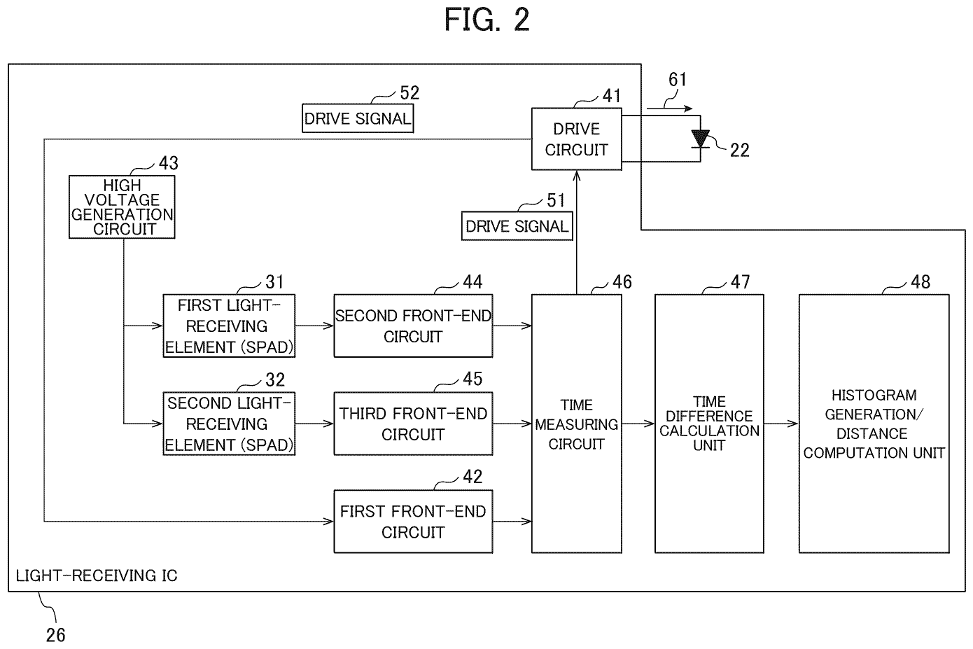

FIG. 2 is a block diagram of a light-receiving IC and a light-emitting element in the ranging sensor in accordance with Embodiment 1.

Referring to FIG. 2, the light-receiving IC 26 includes a drive circuit 41, a first front-end circuit 42, a high voltage generation circuit 43, a second front-end circuit 44, a third front-end circuit 45, a time measuring circuit 46, a time difference calculation unit 47, and a histogram generation/distance computation unit 48.

The drive circuit 41 is fed with a drive signal 51. The drive circuit 41 drives the light-emitting element 22 with a drive current 61 that is in accordance with the inputted drive signal 51. Hence, the light-emitting element 22 emits light in accordance with the drive signal 51. The drive signal 51 contains a pulse signal. Therefore, the emitted light contains a pulsed beam emitted in synchronism with the pulse signal. The pulsed beam contains the first pulsed beam 11 and the second pulsed beam 12. The drive circuit 41 outputs a drive signal 52 that is in accordance with the drive current 61.

The first front-end circuit 42 is fed with the outputted drive signal 52. The first front-end circuit 42 shapes the waveform of the inputted drive signal 52 and outputs a drive signal that has the shaped waveform.

The high voltage generation circuit 43 generates a high voltage and outputs the generated high voltage. The outputted high voltage has, for example, a voltage value of 10 to 20 V.

The outputted high voltage is applied to the first light-receiving element 31. The first light-receiving element 31 operates on the applied high voltage. The first light-receiving element 31 receives the first pulsed beam 11 and outputs the first pulse signal that is in accordance with the received, first pulsed beam 11.

The second front-end circuit 44 is fed with the outputted, first pulse signal. The second front-end circuit 44 shapes the waveform of the inputted, first pulse signal and outputs the first pulse signal that has the shaped waveform.

The outputted high voltage is applied to the second light-receiving element 32. The second light-receiving element 32 operates on the applied high voltage. The second light-receiving element 32 receives the second pulsed beam 12 and outputs the second pulse signal that is in accordance with the received, second pulsed beam 12.

The third front-end circuit 45 is fed with the outputted, second pulse signal. The third front-end circuit 45 shapes the waveform of the inputted, second pulse signal and outputs the second pulse signal that has the shaped waveform.

The time measuring circuit 46 is fed with the drive signal, the first pulse signal, and the second pulse signal that have the shaped waveforms. The time measuring circuit 46 measures the absolute values of an emission time over which the light-emitting element 22 has emitted the first pulsed beam 11, a first reception time over which the first light-receiving element 31 has received the first pulsed beam 11, and a second reception time over which the second light-receiving element 32 has received the second pulsed beam 12 from the inputted drive signal, the inputted, first pulse signal and the inputted, second pulse signal. The time measuring circuit 46 outputs the measured absolute values of the emission time, the first reception time, and the second reception time. The time measuring circuit 46 includes three time digital converters (TDC's) for measuring the absolute values of the emission time, the first reception time, and the second reception time. The time measuring circuit 46 outputs the drive signal 51.

The time difference calculation unit 47 is supplied with the outputted absolute values of the emission time, the first reception time, and the second reception time. The time difference calculation unit 47 calculates a first time difference from the time when the light-emitting element 22 emits the first pulsed beam 11 to the time when the first light-receiving element 31 receives the first pulsed beam 11, based on the supplied absolute values of the emission time and the first reception time. In addition, the time difference calculation unit 47 calculates a second time difference from the time when the light-emitting element 22 emits the first pulsed beam 11 to the time when the second light-receiving element 32 receives the second pulsed beam 12, based on the supplied absolute values of the emission time and the second reception time. The time difference calculation unit 47 outputs the calculated, first time difference and the calculated, second time difference.

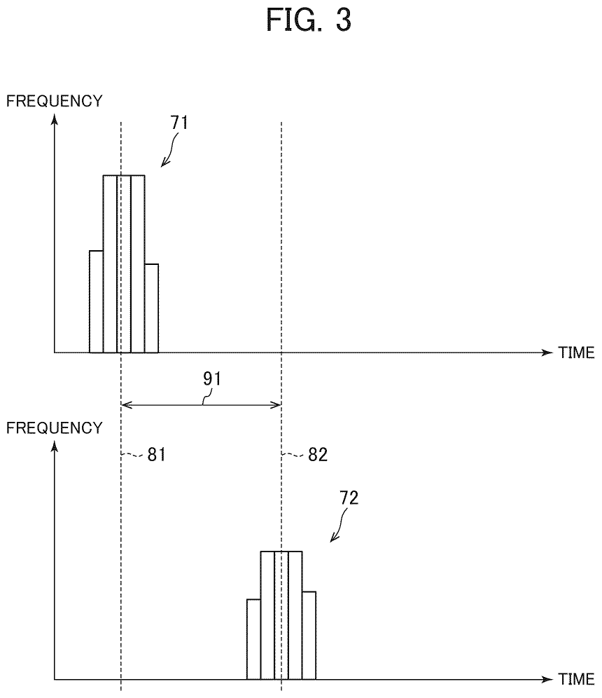

FIG. 3 is a set of diagrams showing examples of a first time difference histogram and a second time difference histogram generated by a histogram generation/distance computation unit in the ranging sensor in accordance with Embodiment 1.

The histogram generation/distance computation unit 48 is fed with the outputted, first time difference and the outputted, second time difference. The histogram generation/distance computation unit 48 generates a first time difference histogram 71 shown in FIG. 3 from a plurality of first time differences fed at mutually different timings. The histogram generation/distance computation unit 48 computes a first center-of-gravity time 81 that gives the center of gravity of the generated, first time difference histogram 71. In addition, the histogram generation/distance computation unit 48 generates a second time difference histogram 72 shown in FIG. 3 from a plurality of second time differences fed at mutually different timings. The histogram generation/distance computation unit 48 computes a second center-of-gravity time 82 that gives the center of gravity of the generated, second time difference histogram 72. The histogram generation/distance computation unit 48 computes a time difference 91 between the computed, first center-of-gravity time 81 and the computed, second center-of-gravity time 82. The histogram generation/distance computation unit 48 computes a distance between the ranging sensor 1 and the target 2 from the computed time difference 91.

The first time difference histogram 71 may be referred to as the reference-side histogram. The second time difference histogram 72 may be referred to as the return-side histogram.

The time difference calculation unit 47 and the histogram generation/distance computation unit 48 may be built around electronic circuits or around a processor that runs the programs stored in the memory.

### 1.3 Drive Circuit

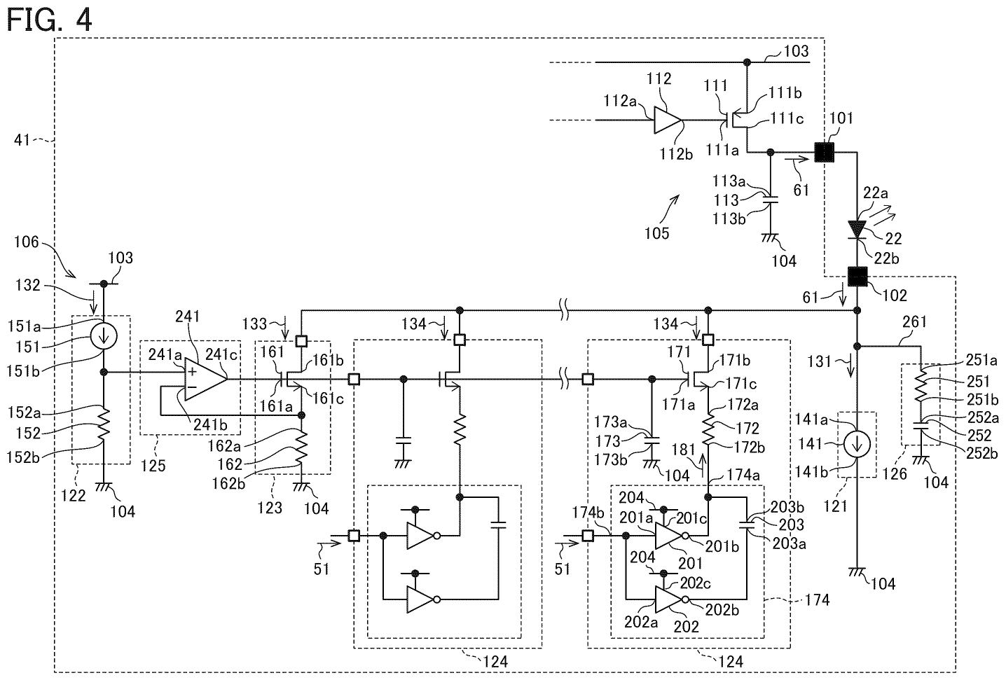

FIG. 4 is a circuit diagram of a drive circuit and a light-emitting element in the ranging sensor in accordance with Embodiment 1.

Referring to FIG. 4, the drive circuit 41 includes an anode-connection terminal 101, a cathode-connection terminal 102, a power supply 103, a ground 104, an anode-side circuit 105, and a cathode-side circuit 106. The light-emitting element 22 includes an anode 22a and a cathode 22b.

The anode 22a and the cathode 22b of the light-emitting element 22 are electrically connected to the anode-connection terminal 101 and the cathode-connection terminal 102 respectively.

The power supply 103 and the ground 104 have a power supply potential and a ground potential respectively.

The anode-side circuit 105 is electrically connected to the power supply 103 and the anode-connection terminal 101. The anode-side circuit 105 passes, from the power supply 103 to the anode-connection terminal 101, the drive current 61 that flows out through the anode-connection terminal 101.

The cathode-side circuit 106 is electrically connected to the cathode-connection terminal 102 and the ground 104. The cathode-side circuit 106 passes, from the cathode-connection terminal 102 to the ground 104, the drive current 61 that flows into the cathode-connection terminal 102.

Hence, the drive current 61 flows out through the anode-connection terminal 101, flows through the light-emitting element 22, and flows into the cathode-connection terminal 102.

### 1.4 Connection Between Drive Circuit and Light-Emitting Element

The anode 22a and the cathode 22b of the light-emitting element 22 are electrically connected to the anode-connection terminal 101 and the cathode-connection terminal 102 via an anode-side gold wire and a cathode-side gold wire respectively.

The anode-side gold wire and the cathode-side gold wire each have a parasitic resistance and a parasitic inductance. The light-emitting element 22 has a parasitic capacitance. These parasitic resistance, parasitic inductance, and parasitic capacitance can be a cause for ringing in the drive current 61.

The cathode-side circuit 106 is subjected to measures for restraining ringing in the drive current 61.

### 1.5 Anode-Side Circuit

Referring to FIG. 4, the anode-side circuit 105 includes a p-channel field effect transistor (FET) 111, a buffer 112, and a capacitor 113. The p-channel FET 111 has a gate 111a, a source 111b, and a drain 111c. The buffer 112 has an input terminal 112a and an output terminal 112b. The capacitor 113 has a first terminal 113a and a second terminal 113b.

The source 111b of the p-channel FET 111 is electrically connected to the power supply 103. The drain 111c of the p-channel FET 111 is electrically connected to the anode-connection terminal 101. Hence, a conduction path is formed that extends from the power supply 103 to the anode-connection terminal 101. The source 111b and the drain 111c are inserted to the formed conduction path. Hence, when the drain 111c is conducting to the source 111b, the anode-side circuit 105 passes the drive current 61 to this conduction path and causes the drive current 61 to flow out through the anode-connection terminal 101. In addition, when the drain 111c is not conducting to the source 111b, the anode-side circuit 105 does not pass the drive current 61 to this conduction path and does not cause the drive current 61 to flow out through the anode-connection terminal 101.

When the gate 111a of the p-channel FET 111 is given an ON potential, the p-channel FET 111 causes the drain 111c of the p-channel FET 111 to conduct to the source 111b of the p-channel FET 111 and causes the drive current 61 to flow out through the drain 111c. When the gate 111a is given an OFF potential, the p-channel FET 111 does not cause the drain 111c to conduct to the source 111b and does not cause the drive current 61 to flow out through the drain 111c. The ON potential is lower than the potential obtained by subtracting the threshold voltage of the p-channel FET 111 from the power supply potential and is, for example, the ground potential. The OFF potential is higher than the potential obtained by subtracting the threshold voltage of the p-channel FET 111 from the power supply potential and is, for example, the power supply potential.

The p-channel FET 111 is, for example, a metal oxide semiconductor (MOS) FET.

The input terminal 112a of the buffer 112 is electrically connected to the control circuit that gives the ON potential and the OFF potential. The output terminal 112b of the buffer 112 is electrically connected to the gate 111a of the p-channel FET 111.

When the input terminal 112a of the buffer 112 is given the ON potential, the buffer 112 gives the ON potential to the output terminal 112b of the buffer 112 and gives the ON potential to the gate 111a of the p-channel FET 111. In addition, when the input terminal 112a is given the OFF potential, the buffer 112 gives the OFF potential to the output terminal 112b and gives the OFF potential to the gate 111a. The input terminal 112a of the buffer 112 has a high input impedance.

The first terminal 113a of the capacitor 113 is electrically connected to the drain 111c of the p-channel FET 111 and to the anode-connection terminal 101 and is electrically connected to the anode 22a of the light-emitting element 22 via the anode-connection terminal 101. The second terminal 113b of the capacitor 113 is electrically connected to the ground 104. Hence, the capacitor 113 is inserted between the drain 111c and the ground 104. Hence, the capacitor 113 can feed at least part of the drive current 61 when the drive current 61 abruptly rises. This enables restraining an abrupt rise of the drive current 61 from affecting the power supply 103. Hence, electromagnetic interference (EMI) attributable to an abrupt rise of the drive current 61 can be restrained.

### 1.6 Cathode-Side Circuit

Referring to FIG. 4, the cathode-side circuit 106 includes a bias current circuit 121, a reference current circuit 122, a mirror current circuit 123, a plurality of driver cells 124, a feedback circuit 125, and a snubber circuit 126.

The bias current circuit 121 is electrically connected to the cathode-connection terminal 102 and the ground 104. The bias current circuit 121 passes a bias current 131 from the cathode-connection terminal 102 to the ground 104. The passed bias current 131 has a constant current value.

The reference current circuit 122 is electrically connected to the power supply 103 and the ground 104. The reference current circuit 122 passes a reference current 132 from the power supply 103 to the ground 104. The passed reference current 132 has a constant current value.

The mirror current circuit 123 is electrically connected to the cathode-connection terminal 102 and the ground 104. The mirror current circuit 123 passes a mirror current 133 from the cathode-connection terminal 102 to the ground 104. The passed mirror current 133 has the same current value as the current value of the reference current 132.

Each driver cell 124 in the plurality of driver cells 124 is electrically connected to the cathode-connection terminal 102 and when turned on, is electrically connected to the ground 104. Each driver cell 124 passes a mirror current 134 from the cathode-connection terminal 102 to the ground 104. The mirror current 134 has a current value 4 times the current value of the reference current 132. The mirror current 134 may have a current value that differs from this current value. Each driver cell 124 is configured so that the current value of the mirror current 134 can be 4 times the current value of the mirror current 133 and is hence configured so that the current value of the mirror current 134 can be 4 times the current value of the reference current 132.

Each driver cell 124 is fed with the drive signal 51. Each driver cell 124 passes the mirror current 134 when the inputted drive signal 51 has a H potential and does not pass the mirror current 134 when the inputted drive signal 51 has a L potential. The H potential is higher than the potential obtained by adding the threshold voltage of an n-channel FET 171 (detailed later) to the ground potential and is, for example, the power supply potential. The L potential is lower than the potential obtained by adding the threshold voltage of the n-channel FET 171 (detailed later) to the ground potential and is, for example, the ground potential.

When the current value of the mirror current 133 is higher than the current value of the reference current 132, the feedback circuit 125 controls the mirror current circuit 123 so as to reduce the current value of the mirror current 133 and controls each driver cell 124 so as to reduce the current value of the mirror current 134. When the current value of the mirror current 133 is lower than the current value of the reference current 132, the feedback circuit 125 controls the mirror current circuit 123 so as to increase the current value of the mirror current 133 and controls each driver cell 124 so as to increase the current value of the mirror current 134. Hence, the feedback circuit 125 performs mirroring of the reference current 132 onto the mirror current 133 so as to equalize the current value of the mirror current 133 and the current value of the reference current 132 and performs mirroring of the reference current 132 onto the mirror current 134 so as to render the current value of the mirror current 134 equal to 4 times the current value of the reference current 132.

The reference current circuit 122, the mirror current circuit 123, and the feedback circuit 125 constitute a circuit for passing the reference current 132 and mirroring the reference current 132 onto the mirror current 134 and constitute a current mirroring circuit in combination with each driver cell 124. The circuit for passing the reference current 132 and mirroring the reference current 132 onto the mirror current 134 may differ from the circuit shown in FIG. 4.

The bias current circuit 121, the mirror current circuit 123, and the plurality of driver cells 124 are inserted and electrically connected in parallel between the cathode-connection terminal 102 and the ground 104. Hence, the drive current 61 flowing into the cathode-connection terminal 102 branches out to the bias current circuit 121, the mirror current circuit 123, and the plurality of driver cells 124. Therefore, the drive current 61 is constituted by the bias current 131, the mirror current 133, and the plurality of mirror currents 134.

The plurality of driver cells 124, electrically connected in parallel, enables driving the light-emitting element 22 with the drive current 61 that has a higher current value than the current value of the mirror current 134 that can be fed by each driver cell 124.

The snubber circuit 126 is electrically connected to the cathode-connection terminal 102 and the ground 104. The snubber circuit 126 restrains ringing in the drive current 61.

### 1.7 Waveforms of Drive Signal and Drive Current

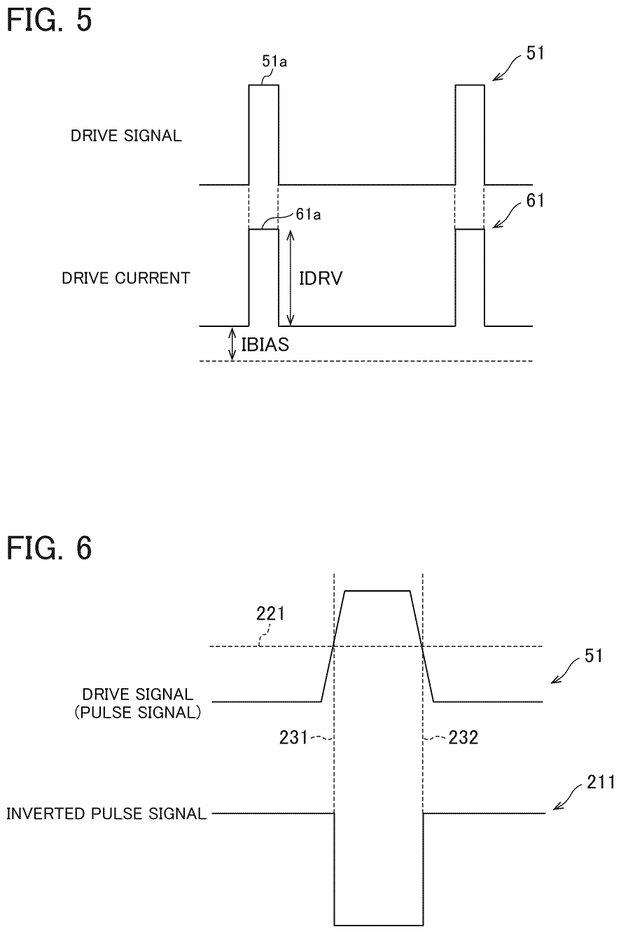

FIG. 5 is a diagram showing a waveform of a drive signal inputted to a drive circuit in the ranging sensor in accordance with Embodiment 1 and a waveform of a drive current outputted from this drive circuit.

Referring to FIG. 5, the drive signal 51 contains a pulse signal 51a. In addition, the drive current 61 contains a pulsed current 61a.

The drive circuit 41 outputs the pulsed current 61a in response to the input of the pulse signal 51a.

While the pulse signal 51a is not being inputted, the drive circuit 41 outputs the drive current 61 that has a current value IBAIS that is a sum of the current value of the bias current 131 and the current value of the mirror current 133. While the pulse signal 51a is being inputted, the drive circuit 41 outputs the drive current 61 that has a current value that is a sum of the current value IBAIS and a current value DRV that is a sum of the current values of the plurality of mirror currents 134.

### 1.8 Bias Current Circuit

Referring to FIG. 4, the bias current circuit 121 includes a current source 141. The current source 141 has a first terminal 141a and a second terminal 141b.

The first terminal 141a of the current source 141 is electrically connected to the cathode-connection terminal 102. The second terminal 141b of the current source 141 is connected to the ground 104. Hence, a conduction path is formed that extends from the cathode-connection terminal 102 to the ground 104. The current source 141 is inserted to the formed conduction path.

The current source 141 passes the bias current 131 from the first terminal 141a of the current source 141 to the second terminal 141b of the current source 141. Hence, the bias current circuit 121 passes the bias current 131 from the cathode-connection terminal 102 to the ground 104.

### 1.9 Reference Current Circuit

Referring to FIG. 4, the reference current circuit 122 includes a constant current source 151 and a resistor 152. The constant current source 151 has a first terminal 151a and a second terminal 151b. The resistor 152 has a first terminal 152a and a second terminal 152b.

The first terminal 151a of the constant current source 151 is electrically connected to the power supply 103. The second terminal 151b of the constant current source 151 is electrically connected to the first terminal 152a of the resistor 152. The second terminal 152b of the resistor 152 is electrically connected to the ground 104. Hence, a conduction path is formed that extends from the power supply 103 to the ground 104. The constant current source 151 and the resistor 152 are inserted to the formed conduction path. The constant current source 151 and the resistor 152 both thus inserted are electrically connected in series.

The constant current source 151 passes the reference current 132 from the first terminal 151a of the constant current source 151 to the second terminal 151b of the constant current source 151. Hence, the reference current circuit 122 passes the reference current 132 from the power supply 103 to the ground 104. The second terminal 151b of the constant current source 151 and the first terminal 152a of the resistor 152 are given an electrical potential in accordance with the current value of the reference current 132 thus passed. The given electrical potential is the product of the current value of the reference current 132 and the resistance value of the resistor 152.

### 1.10 Mirror Current Circuit

Referring to FIG. 4, the mirror current circuit 123 includes a n-channel FET 161 and a resistor 162. The n-channel FET 161 has a gate 161a, a drain 161b, and a source 161c. The resistor 162 has a first terminal 162a and a second terminal 162b.

The drain 161b of the n-channel FET 161 is electrically connected to the cathode-connection terminal 102. Therefore, the mirror current 133, which is part of the drive current 61, flows into the drain 161b. The source 161c of the n-channel FET 161 is electrically connected to the first terminal 162a of the resistor 162. The second terminal 162b of the resistor 162 is electrically connected to the ground 104. Hence, a conduction path is formed that extends from the cathode-connection terminal 102 to the ground 104. The drain 161b, the source 161c, and the resistor 162 are inserted to the formed conduction path. The drain 161b, the source 161c, and the resistor 162, all thus inserted, are electrically connected in series.

The n-channel FET 161 passes, from the drain 161b of the n-channel FET 161 to the source 161c of the n-channel FET 161, the mirror current 133 that is in accordance with the electrical potential given to the gate 161a of the n-channel FET 161. Hence, the mirror current circuit 123 passes, from the cathode-connection terminal 102 to the ground 104, the mirror current 133 that is in accordance with the electrical potential given to the gate 161a. The current value of the mirror current 133 thus passed increases with an increase in this electrical potential. The source 161c of the n-channel FET 161 and the first terminal 162a of the resistor 162 are given an electrical potential that is in accordance with the current value of the passed mirror current 133. The given electrical potential is the product of the current value of the mirror current 133 and the resistance value of the resistor 162.

The gate 161a of the n-channel FET 161 is electrically connected to the feedback circuit 125. Hence, the gate 161a is given an electrical potential that renders the current value of the mirror current 133 equal to the current value of the reference current 132. Hence, the mirror current circuit 123 is controlled so as to pass the mirror current 133 that has the same current value as the current value of the reference current 132.

The source 161c of the n-channel FET 161 and the first terminal 162a of the resistor 162 are electrically connected to the feedback circuit 125. Hence, the mirror current circuit 123 enables transferring the electrical potential that is in accordance with the current value of the mirror current 133 to the feedback circuit 125.

The n-channel FET 161 is a MOSFET.

### 1.11 Driver Cell

Referring to FIG. 4, each driver cell 124 includes the n-channel FET 171, a resistor 172, a capacitor 173, and a source drive circuit 174. The n-channel FET 171 has a gate 171a, a drain 171b, and a source 171c. The resistor 172 has a first terminal 172a and a second terminal 172b. The capacitor 173 has a first terminal 173a and a second terminal 173b. The source drive circuit 174 has a first terminal 174a and a second terminal 174b.

The drain 171b of the n-channel FET 171 is electrically connected to the cathode-connection terminal 102. Therefore, the mirror current 134, which is part of the drive current 61, flows into the drain 171b. The source 171c of the n-channel FET 171 is electrically connected to the first terminal 172a of the resistor 172. The second terminal 172b of the resistor 172 is electrically connected to the first terminal 174a of the source drive circuit 174. Hence, a conduction path is formed that extends from the cathode-connection terminal 102 to the first terminal 174a. The drain 171b, the source 171c, and the resistor 172 are inserted to the formed conduction path. The drain 171b, source 171c, and resistor 172, all thus inserted, are electrically connected in series.

The n-channel FET 171 passes, from the drain 171b of the n-channel FET 171 to the source 171c of the n-channel FET 171, the mirror current 134 that is in accordance with the electrical potential given to the gate 171a of the n-channel FET 171. Hence, each driver cell 124 passes, from the cathode-connection terminal 102 to the first terminal 174a of the source drive circuit 174, the mirror current 134 that is in accordance with the electrical potential given to the gate 171a. The current value of the mirror current 134 thus passed increases with an increase in this electrical potential.

The gate 171a of the n-channel FET 171 is electrically connected to the feedback circuit 125. Hence, the gate 171a is given such an electrical potential that the current value of the mirror current 134 can be 4 times the current value of the reference current 132. Hence, the mirror current circuit 123 is controlled so that the mirror current 133 can flow that has a current value 4 times the current value of the reference current 132.

The n-channel FET 171 is a MOSFET.

The resistor 172 has a resistance value ¼ times the resistance value of the resistor 162. Hence, the current value of the mirror current 134 can be rendered equal to 4 times the current value of the mirror current 133.

The first terminal 173a of the capacitor 173 is electrically connected to the gate 171a of the n-channel FET 171. The second terminal 173b of the capacitor 173 is electrically connected to the ground 104. Hence, the capacitor 173 is inserted between the gate 171a and the ground 104 to ground the gate 171a by means of alternating current. The capacitance value of the capacitor 173 is specified so as to have a sufficiently small capacitive impedance at the frequencies of large frequency components of the drive signal 51.

The second terminal 174b of the source drive circuit 174 is fed with the drive signal 51. The source drive circuit 174 causes a signal 181 that is in accordance with the drive signal 51 inputted to the second terminal 174b to be outputted from the first terminal 174a of the source drive circuit 174. The first terminal 174a is electrically connected to the source 171c of the n-channel FET 171 via the resistor 172. Therefore, the source drive circuit 174 drives the source 171c with the signal 181 so that the mirror current 134 can flow.

The source drive circuit 174 causes the signal 181 to have an electrical potential equal to the L potential so that the mirror current 134 can flow when the drive signal 51 has the H potential and causes the signal 181 to have an electrical potential equal to the H potential so that the mirror current 134 does not flow when the drive signal 51 has the L potential.

When the gate 171a of the n-channel FET 171 is grounded by means of alternating current, and the source 171c of the n-channel FET 171 is driven by the signal 181, the modulation by the signal 181 becomes unlikely to be affected by the mirror capacitance of the n-channel FET 171. Hence, the modulation by the signal 181 can be implemented at high speed, thereby enabling the light-emitting element 22 to emit a pulsed beam with a short pulse width.

### 1.12 Source Drive Circuit

Referring to FIG. 4, the source drive circuit 174 includes a first inverter 201, a second inverter 202, a capacitor 203, and a constant voltage power supply 204. The first inverter 201 has an input terminal 201a, an output terminal 201b, and a power supply terminal 201c. The second inverter 202 has an input terminal 202a, an output terminal 202b, and a power supply terminal 202c. The capacitor 203 has a first terminal 203a and a second terminal 203b.

The input terminal 201a of the first inverter 201 and the input terminal 202a of the second inverter 202 are electrically connected to the time measuring circuit 46. The output terminal 201b of the first inverter 201 is electrically connected to the second terminal 172b of the resistor 172. The output terminal 202b of the second inverter 202 is electrically connected to the first terminal 203a of the capacitor 203. The second terminal 203b of the capacitor 203 is electrically connected to the second terminal 172b of the resistor 172. Hence, the output terminal 201b of the first inverter 201 is connected directly to the second terminal 172b. The output terminal 202b of the second inverter 202 is connected to the second terminal 172b via the capacitor 203. The power supply terminal 201c of the first inverter 201 and the power supply terminal 202c of the second inverter 202 are electrically connected to the constant voltage power supply 204.

The input terminal 201a of the first inverter 201 and the input terminal 202a of the second inverter 202 are fed with the drive signal 51. The first inverter 201 and the second inverter 202 cause an inverted pulse signal obtained by inverting the inputted drive signal 51 to be outputted to the output terminal 201b of the first inverter 201 and to the output terminal 202b of the second inverter 202 respectively. Hence, an electrical potential in accordance with the inverted pulse signal is given to the second terminal 172b of the resistor 172. Hence, the signal that drives the source 171c of the n-channel FET 171 is the inverted pulse signal obtained by inverting the drive signal 51.

The output terminal 202b of the second inverter 202 is connected to the second terminal 172b of the resistor 172 via the capacitor 203 and is hence coupled to the second terminal 172b by means of alternating current (AC). Hence, the electrical potential of the inverted pulse signal can quickly rise.

FIG. 6 is a diagram showing a waveform of a drive signal inputted to the input terminals of a first inverter and a second inverter in a drive circuit in the ranging sensor in accordance with Embodiment 1 and a waveform of an inverted pulse signal outputted from the output terminals of the first inverter and the second inverter.

Referring to FIG. 6, the electrical potential of an inverted pulse signal 211 outputted from the output terminal 201b of the first inverter 201 and the output terminal 202b of the second inverter 202 falls from the H potential to the L potential at a timing 231 at which the electrical potential of the drive signal 51 inputted to the input terminal 201a of the first inverter 201 and the input terminal 202a of the second inverter 202 rises beyond a threshold potential 221. The electrical potential of an inverted pulse signal 211 rises from the L potential to the H potential at a timing 232 at which the electrical potential of the drive signal 51 falls below the threshold potential 221.

The electrical potential of the drive signal 51 takes time to rise from the L potential to the H potential and takes time also to fall from the H potential to the L potential. Therefore, when the threshold potential 221 is changed, the timing 231 and the timing 232 change, and the waveform of the inverted pulse signal 211 also changes.

The threshold potential 221 changes when the electrical potential given to the power supply terminal 201c of the first inverter 201 and the power supply terminal 202c of the second inverter 202 is changed. Therefore, the waveform of the inverted pulse signal 211 changes when the electrical potential given to the power supply terminal 201c and the power supply terminal 202c is changed. However, when the power supply terminal 201c and the power supply terminal 202c are electrically connected to the constant voltage power supply 204, and a stable electrical potential is given to the power supply terminal 201c and the power supply terminal 202c, the waveform of the inverted pulse signal 211 can be stabilized.

### 1.13 Feedback Circuit

Referring to FIG. 4, the feedback circuit 125 includes a computation amplifier 241. The computation amplifier 241 has a non-inverting input terminal 241a, an inverting input terminal 241b, and an output terminal 241c.

The non-inverting input terminal 241a is electrically connected to the second terminal 151b of the constant current source 151 and to the first terminal 152a of the resistor 152. The inverting input terminal 241b is electrically connected to the source 161c of the n-channel FET 161 and to the first terminal 162a of the resistor 162. The output terminal 241c is electrically connected to the gate 161a of the n-channel FET 161 and to the gate 171a of the n-channel FET 171.

Hence, the non-inverting input terminal 241a is given an electrical potential equal to the product of the current value of the reference current 132 and the resistance value of the resistor 152. The inverting input terminal 241b is given an electrical potential equal to the product of the current value of the mirror current 133 and the resistance value of the resistor 162.

The computation amplifier 241 gives, to the output terminal 241c of the computation amplifier 241, an electrical potential obtained by subtracting the electrical potential given to the inverting input terminal 241b of the computation amplifier 241 from the electrical potential given to the non-inverting input terminal 241a of the computation amplifier 241 to obtain an electrical potential difference and then multiplying the electrical potential difference by a gain.

The resistance value of the resistor 162 is equal to the resistance value of the resistor 152. Therefore, this electrical potential difference is proportional to the current value difference obtained by subtracting the current value of the mirror current 133 from the current value of the reference current 132. Therefore, the electrical potentials given to the output terminal 241c of the computation amplifier 241, the gate 161a of the n-channel FET 161, and the gate 171a of the n-channel FET 171 are proportional to the current value difference. Hence, when this current value difference is greater than or equal to 0, the feedback circuit 125 increases the electrical potentials given to the gate 161a of the n-channel FET 161 and the gate 171a of the n-channel FET 171 and increases the current values of the mirror current 133 and the mirror current 134. In addition, when this current value difference is less than 0, the feedback circuit 125 reduces the electrical potentials given to the gate 161a of the n-channel FET 161 and the gate 171a of the n-channel FET 171 and reduces the current values of the mirror current 133 and the mirror current 134. Hence, the feedback circuit 125 performs mirroring of the reference current 132 onto the mirror current 133 so as to equalize the current value of the mirror current 133 and the current value of the reference current 132 and performs mirroring of the reference current 132 onto the mirror current 134 so as to render the current value of the mirror current 134 equal to 4 times the current value of the reference current 132.

### 1.14 Snubber Circuit

Referring to FIG. 4, the snubber circuit 126 includes a resistor 251 and a capacitor 252. The resistor 251 has a first terminal 251a and a second terminal 251b. The capacitor 252 has a first terminal 252a and a second terminal 252b.

The first terminal 251a of the resistor 251 is electrically connected to the cathode-connection terminal 102. The second terminal 251b of the resistor 251 is electrically connected to the first terminal 252a of the capacitor 252. The second terminal 252b of the capacitor 252 is electrically connected to the ground 104. Hence, a conduction path 261 is formed that extends from the cathode-connection terminal 102 to the ground 104. The resistor 251 and the capacitor 252 are inserted to the formed the conduction path 261. The resistor 251 and the capacitor 252 thus inserted are electrically connected in series to constitute the snubber circuit 126.

The snubber circuit 126 serves as a ringing correction circuit for restraining ringing in the drive current 61.

### 1.15 Restraining Ringing

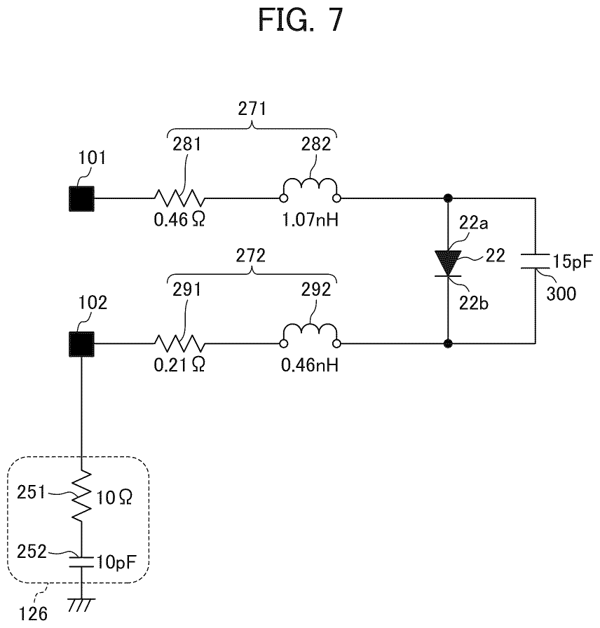

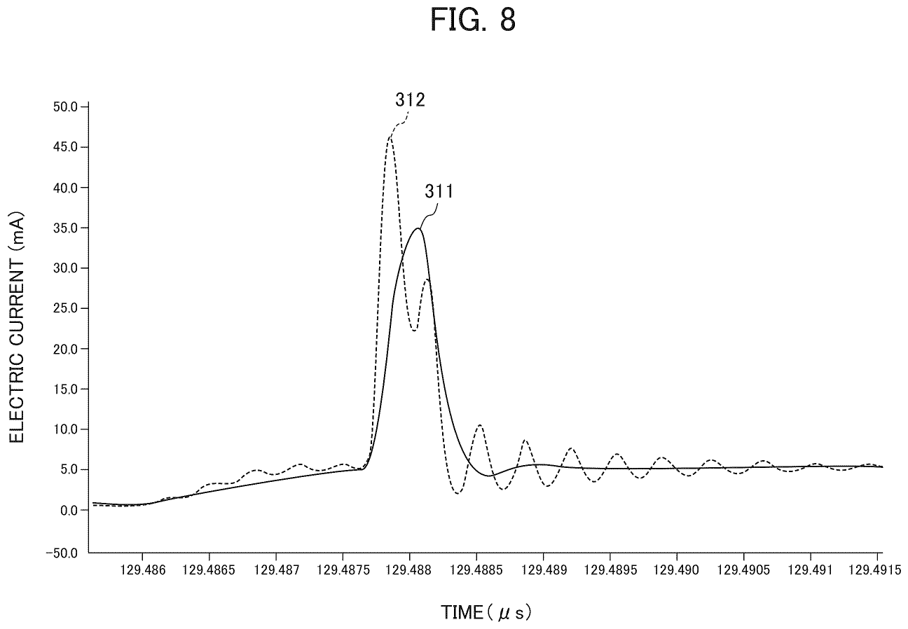

FIG. 7 is a circuit diagram of an equivalent circuit of a light-emitting element, an anode-side gold wire, a cathode-side gold wire, and a snubber circuit in the ranging sensor in accordance with Embodiment 1. FIG. 8 is a graph representing an exemplary waveform of a drive current outputted by a drive circuit in the ranging sensor in accordance with Embodiment 1 and an exemplary waveform of a drive current outputted by the drive circuit when no snubber circuit is provided in the drive circuit.

Referring to FIG. 7, an anode-side gold wire 271 for electrically connecting the anode 22a of the light-emitting element 22 to the anode-connection terminal 101 has a parasitic resistance 281 and a parasitic inductor 282. FIG. 7 shows an example where the parasitic resistance 281 has a resistance value of 0.46Ω, and the parasitic inductor 282 has an inductance value of 1.07 nH.

A cathode-side gold wire 272 for electrically connecting the cathode 22b of the light-emitting element 22 to the cathode-connection terminal 102 has a parasitic resistance 291 and a parasitic inductor 292. FIG. 7 shows an example where the parasitic resistance 291 has a resistance value of 0.21Ω, and the parasitic inductor 292 has an inductance value of 0.46 nH.

The light-emitting element 22 includes a parasitic capacitor 300. FIG. 7 shows an example where the parasitic capacitor 300 has a capacitance value of 15 pF.

When no snubber circuit 126 is provided even in the presence of the parasitic resistance 281, the parasitic inductor 282, the parasitic resistance 291, the parasitic inductor 292, and the parasitic capacitor 300, large ringing occurs in the drive current 61 as indicated by a waveform 312 in FIG. 8. However, when the snubber circuit 126 is provided even in the presence of the parasitic resistance 281, the parasitic inductor 282, the parasitic resistance 291, the parasitic inductor 292, and the parasitic capacitor 300, no large ringing occurs in the drive current 61 as indicated by a waveform 311 in FIG. 8.

The resistance value of the resistor 251 and the capacitance value of the capacitor 252 are adjusted in accordance with the resistance value of the parasitic resistance 281, the inductance value of the parasitic inductor 282, the resistance value of the parasitic resistance 291, the inductance value of the parasitic inductor 292, and the capacitance value of the parasitic capacitor 300. FIG. 7 shows an example where the resistor 251 has a resistance value of 10Ω, and the capacitor 252 has a capacitance value of 10 pF.

### 2 Embodiment 2

The following will describe differences of Embodiment 2 from Embodiment 1. Embodiment 2 adopts the same structure as Embodiment 1 unless otherwise described.

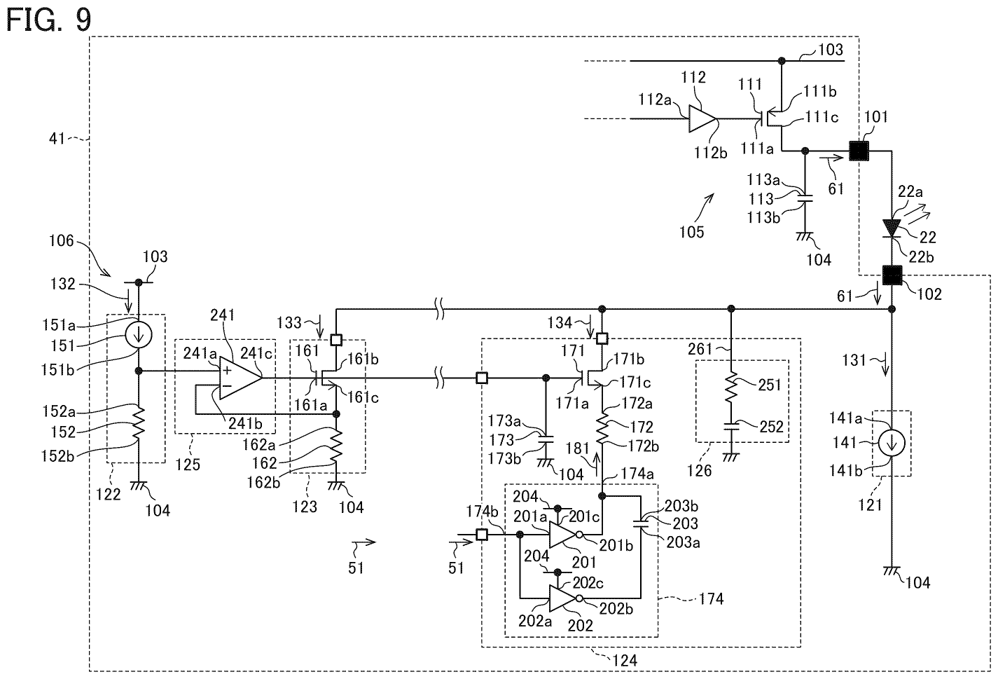

FIG. 9 is a circuit diagram of a drive circuit in a ranging sensor in accordance with Embodiment 2.

Referring to FIG. 9, in Embodiment 2, each driver cell 124 includes a conduction path 261 and a snubber circuit 126.

The conduction path 261 extends from the cathode-connection terminal 102 to the ground 104. The snubber circuit 126 is inserted to the conduction path 261.

Since each driver cell 124 includes a snubber circuit 126, the plurality of driver cells 124 include a plurality of snubber circuits 126 respectively. The plurality of snubber circuits 126 are electrically connected in parallel with each other.

Hence, when the number of the plurality of driver cells 124 is equal to N, the resistance value of the resistor 251 in Embodiment 2 can be made equal to N times the resistance value of the resistor 251 in Embodiment 1. In addition, the capacitance value of the capacitor 252 in Embodiment 2 can be made equal to 1/N times the capacitance value of the capacitor 252 in Embodiment 1. Hence, the snubber circuit 126 can be readily incorporated into the light-receiving IC 26 into which it is difficult to incorporate a resistor with a small resistance value and a capacitor with a large capacitor value.

### 3 Embodiment 3

The following will describe differences of Embodiment 3 from Embodiment 2. Embodiment 3 adopts the same structure as Embodiment 2 unless otherwise described.

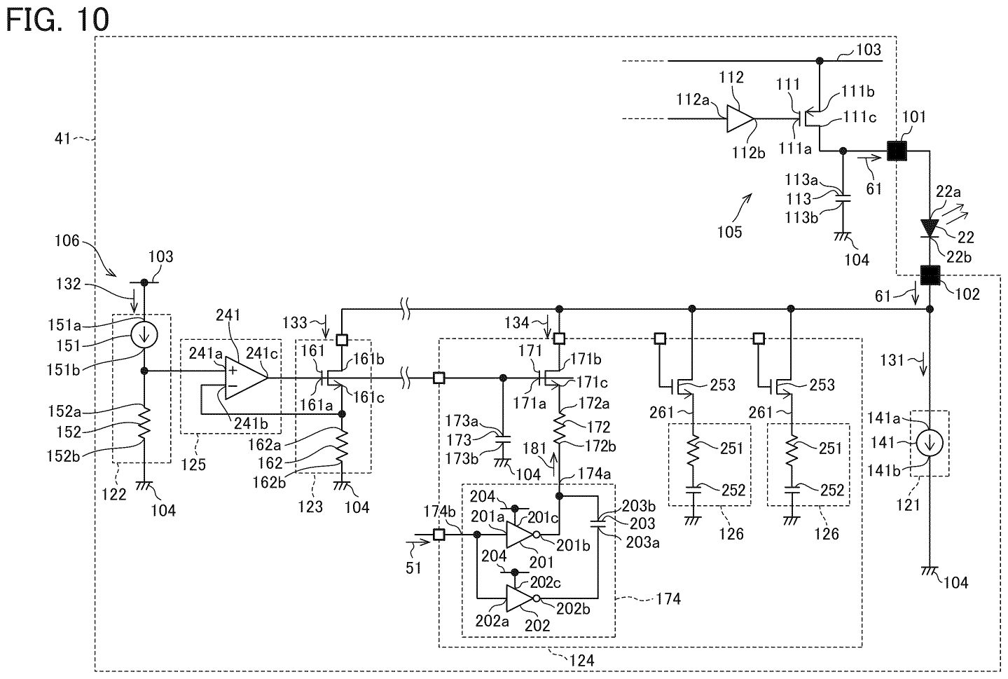

FIG. 10 is a circuit diagram of a drive circuit in a ranging sensor in accordance with Embodiment 3.

Referring to FIG. 10, in Embodiment 3, each driver cell 124 includes a plurality of conduction paths 261, a plurality of snubber circuits 126, and a plurality of switches 253.

The plurality of snubber circuits 126 are inserted to the plurality of conduction paths 261 respectively. The plurality of switches 253 are inserted to the plurality of conduction paths 261 respectively.

The plurality of switches 253 switch the state where the plurality of conduction paths 261 are closed and the state where the plurality of conduction paths 261 are open respectively.

The snubber circuit 126 inserted to the closed conduction path 261 contributes to restraining of ringing in the drive current 61.

In Embodiment 3, the ringing can be restrained in accordance with parasitic resistance, parasitic capacitance, and parasitic inductance by selecting the number of the closed conduction paths 261.

The present disclosure is not limited to the description of the embodiments and examples above. Any structure detailed in the embodiments and examples may be replaced by a practically identical structure, a structure that delivers practically the same effect and function, or a structure that achieves practically the same purpose.

What is claimed is:

1. A drive circuit comprising:
a n-channel field effect transistor including:
a gate;
a drain into which an electric current that is part of a drive current that drives a light-emitting element flows; and
a source;
a capacitor that grounds the gate by means of alternating current; and
a source drive circuit that drives the source through a signal that is in accordance with an inputted pulse signal.

2. The drive circuit according to claim 1, wherein
the source drive circuit includes:
an inverter including:
an input terminal to which the pulse signal is inputted;
an output terminal that outputs an inverted pulse signal obtained by inverting the pulse signal; and
a power supply terminal; and
a constant voltage power supply electrically connected to the power supply terminal, and
the signal is the inverted pulse signal.

3. The drive circuit according to claim 1 further comprising:
a ground;
a conduction path that extends from the drain to the ground; and
a snubber circuit inserted to the conduction path.

4. The drive circuit according to claim 3 further comprising a plurality of driver cells each including the n-channel field effect transistor, the capacitor, the source drive circuit, the conduction path, and the snubber circuit.

5. The drive circuit according to claim 1 further comprising:
a ground;
a plurality of conduction paths that extend from the drain to the ground;
a plurality of snubber circuits inserted to the plurality of conduction paths respectively; and
a plurality of switches inserted to the plurality of conduction paths respectively.

6. The drive circuit according to claim 1, wherein
the gate is a first gate,
the drain is a first drain,
the source is a first source, and
the drive circuit further comprises;
a p-channel field effect transistor including:
a second gate;
a second drain through which the drive current flows out; and
a second source;
a power supply electrically connected to the second source;
a ground; and
a capacitor inserted between the second drain and the ground.

7. The drive circuit according to claim 1 further comprising a circuit that passes a reference current to perform mirroring the reference current onto the electric current.

8. The drive circuit according to claim 1, wherein the light-emitting element is a vertical-cavity surface-emitting diode.

9. A ranging sensor comprising:
the drive circuit according to claim 1;
the light-emitting element; and
a light-receiving element.
